(19) United States
(12) Patent Application Publication
(10) Pub. No.: US 2015/0034486 A1
(43) Pub. Date: Feb. 5, 2015

(54) POLARIZABLE CONNECTION STRUCTURE AND DEVICE INCLUDING THE SAME

(71) Applicant: CANON KABUSHIKI KAISHA, Tokyo (JP)

(72) Inventor: Hideyuki Sugioka, Ebina-shi (JP)

(21) Appl. No.: 14/323,012

(22) Filed: Jul. 3, 2014

(30) Foreign Application Priority Data
Jul. 30, 2013 (JP) 2013-157365

(51) Int. Cl. F04B 19/00; H01L 41/18; G01N 27/447; B01F 13/00; B01J 13/08; H01L 41/09; F04B 17/00

(52) U.S. Cl. CPC F04B 19/006; H01L 41/09; H01L 41/18; F04B 17/003; B01F 13/0003; B01J 13/08; G01N 27/44756
USPC 204/600; 310/328; 417/48

(57) ABSTRACT

Provided is a device capable of functionalizing a micro-motion of a polarizable microstructure. A structure includes a plurality of polarizable structures, each having an electrically polarizable conductive part on a surface thereof, and a connector body having one of mobility and deformability, for connecting the plurality of polarizable structures to each other.

### BACKGROUND OF THE INVENTION

1. Field of the Invention

The present invention relates to a polarizable connection structure to be applied to mixing devices, microparticle stabilization devices, microparticle removal/separation devices, and artificial muscles, and to a device including the polarizable connection structure.

2. Description of the Related Art

A micropump using interfacial properties, in particular, electroosmosis, has a relatively simple structure, and is also easy to mount in a micro-flow path. For the reasons described above, the micropump is used in the field of a micro-total analysis system (μTAS) and the like.

Under the situations described above, in recent years, a micropump using induced-charge electroosmosis (ICEO) has attracted attention for the following reasons. With the above-mentioned micropump, a flow rate of a liquid can be increased, and a chemical reaction occurring between an electrode and the liquid can be suppressed because an AC drive can be performed.

In particular, U.S. Pat. No. 7,081,189 and Physical Review Letters, 92, 066101 (2004) by M. Z. Bazant and T. M. Squires disclose the following micromixer and micropump. Specifically, the micromixer and the micropump are respectively a mixer (mixing device) and a pump (liquid feeding device) which use the induced-charge electroosmosis. The micromixer utilizes a vortex caused by an ICEO flow around a cylindrical metal post, whereas the micropump utilizes the ICEO flow.

Physical Review, E75, 011503 (2007) by K. A. Rose et al. reports a rotation of a microrod using induced-charge electrophoresis (ICEP). Physical Review Letters, 100, 058302 (2008) by S. Gangwal, O. J. Cayre, M. Z. Bazant, and O. D. Velev discloses an electrophoresis phenomenon of metal particles, each being half coated with an insulator.

Physical Review, E80, 016315 (2009) by H. Sugioka discloses the following. Specifically, distinct columnar structures can be generated at a particle concentration which is equal to or more than a given threshold value when an electric field is applied to a group of metal particles in an electrolyte.

U.S. Pat. No. 7,081,189, Physical Review Letters, 92, 066101 (2004), Physical Review, E75, 011503 (2007), and Physical Review Letters, 100, 058302 (2008) cited above examine a motion of a polarizable microstructure as a single body. However, functions which can be fulfilled by the single polarizable structure as a single body are limited. On the other hand, when the polarizable structures can be moved collectively, the functions can be fulfilled on a larger scale.

### SUMMARY OF THE INVENTION

The present invention is directed to providing a device capable of converting micro-motions of polarizable microstructures into a collective motion to allow functions to be fulfilled on a larger scale in accordance with a desired design purpose, which is difficult in the related art.

According to one aspect of the present invention, there is provided a polarizable connection structure including: a plurality of polarizable structures, each having an electrically polarizable conductive part on a surface thereof; and a connector body having one of mobility and deformability, for connecting the plurality of polarizable structures to each other.

The device provided by the present invention includes the structure, a liquid chamber for containing the structure and an electrolyte solution therein, and an electric-field application unit.

Further features of the present invention will become apparent from the following description of exemplary embodiments with reference to the attached drawings.

### BRIEF DESCRIPTION OF THE DRAWINGS

FIG. 1 is a diagram illustrating a device according to Example 1 of the present invention.

FIGS. 2A and 2B are diagrams illustrating an operation principle of a polarizable connection structure.

FIGS. 3A, 3B, 3C and 3D are diagrams illustrating examples of the polarizable connection structure.

FIG. 4 is a diagram illustrating a device according to Example 2 of the present invention.

FIG. 5 is a diagram illustrating a device according to Example 3 of the present invention.

FIG. 6 is a diagram illustrating a device according to Example 4 of the present invention.

FIG. 7 is a diagram illustrating a device according to Example 5 of the present invention.

FIG. 8 is a diagram illustrating a device according to Example 6 of the present invention.

### DESCRIPTION OF THE EMBODIMENTS

Preferred embodiments of the present invention will now be described in detail in accordance with the accompanying drawings.

A polarizable connection structure according to the present invention includes: a plurality of polarizable structures, each having an electrically polarizable conductive part on a surface thereof; and a connector body having one of mobility and deformability, for connecting the plurality of polarizable structures to each other.

A material, a shape, a size, and a weight of the polarizable structure are not particularly limited as long as the polarizable structure has the electrically polarizable conductive part on the surface thereof and, when an electric field is applied in an electrolyte solution, an electroosmotic flow is generated around the surface of the polarizable structure such that the polarizable structure can move in the electrolyte solution by the electroosmotic flow.

As the polarizable structure having the polarizable part, a conductor such as gold, platinum, and carbon, composite-material particles made of conductor microparticles and a dielectric such as styrene, polyimide, polyvinyl alcohol, and polyethylene, and particles, each having a dielectric surface partially or entirely coated with gold, platinum, or carbon, can be used.

The shape of the polarizable structure can be selected from various shapes including a sphere, an elliptical sphere, an elliptic cylinder, and cuboids. When the polarizable structure has the spherical shape, a radius may be from 0.01 μm to 1,000 μm. When the polarizable structure has the elliptical spherical shape or the elliptic cylindrical shape, a minor radius may be 0.01 μm to 100 μm and a ratio of a major axis and the minor axis may be more than 1:1 and equal to or less than 1,000:1. The terms “spherical shape”, “elliptical spherical shape”, “elliptic cylindrical shape”, and the like do not mean that the shape need be exactly spherical, elliptical spherical, elliptic cylindrical, and the like, and a certain amount of error is allowable.

A material, a shape, a size, and a weight of a connector body having any of mobility and deformability are not particularly limited as long as the connector body can connect the polarizable structures to each other or the polarizable structure and another material to each other. The connector body of the present invention is movable or deformable. Therefore, a complex or predetermined stretching vibration is induced between the polarizable structures due to a repulsion force and an attractive force between the polarizable structures, which are described later.

As the connector body, a linear or a strip-like insulating fiber resin having elasticity such as nylon and Teflon (trade names), or a silicon resin such as polydimethylsiloxane (PDMS) and a silicon rubber can be used. The connector body may have a linear structure or a curved structure.

A method of bonding the polarizable structure and the connector body is not particularly limited. For example, when the polarizable structure is made of a precious metal such as gold or platinum, and the connector body is made of a thermoplastic resin such as polyethyrene, polystyrene, or vinyl chloride, the polarizable structure and the connector body can be bonded by thermofusion. When the polarizable structure is a perforated structure made of gold or platinum, which has a hole structure processed by a microfabrication technology such as a micro-electro-mechanical-system (MEMS) technology or a nano-electro-mechanical-system (NEMS) technology, and the connector body is a three-dimensional pin structure which can fit to the perforated structure, the connector body being made of an epoxy resin such as SU-8 and fabricated by the MEMS or NEMS technology similarly to the polarizable structure, the polarizable structure and the connector body can be connected to each other by pinning using the three-dimensional pin structure.

The number of polarizable structures for each polarizable connection structure is not particularly limited. Two polarizable structures may be connected to form the polarizable connection structure, or at least three polarizable structures may be connected to form the polarizable connection structure. For example, two to fifty, two to fifteen, two to ten, two to five, or three to five polarizable structures may be connected to form the polarizable connection structure. Alternatively, at least fifty polarizable structures may be connected.

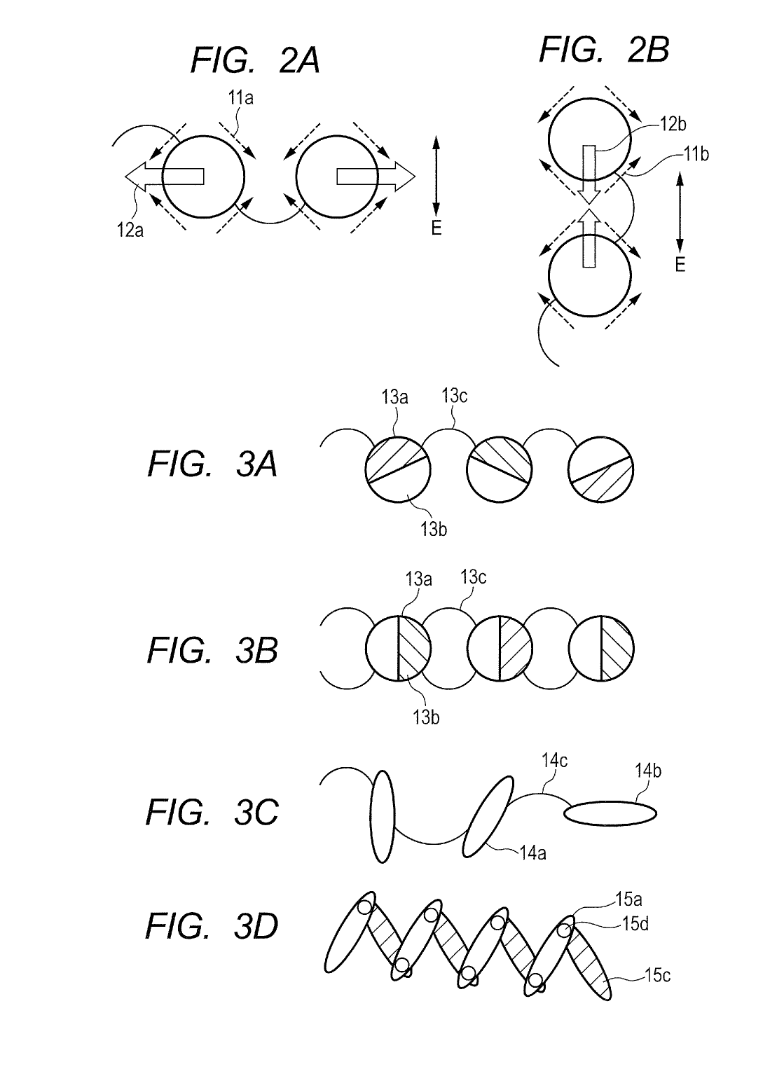

When an electric field is applied to the electrolyte solution in a state in which the polarizable connection structures according to the present invention are moving freely in the electrolyte solution, an electric double layer is formed on a surface of the conductive part of each of the polarizable structures. The electroosmotic flow is generated in a direction approximately along a direction of the electric field or a direction opposite thereto depending on the sign of ions forming the electric double layer. When the polarizable structures are connected in a direction perpendicular to an electric-field direction E, directions of slipping velocities 11a are opposed to each other between the polarizable structures, as illustrated in FIG. 2A. Therefore, repulsion forces 12a act between the polarizable structures. Moreover, when the polarizable structures are connected in parallel to the electric-field direction E, the directions of the slipping velocities 11b separate away from each other between the polarizable structures, as illustrated in FIG. 2B. Therefore, attractive forces 12b act between the polarizable structures. Even when the direction of the applied electric field is reversed, ions having the opposite sign are accumulated in the surface of the conductive part to form the electric double layer. Therefore, the repulsion forces still act between the polarizable structures in the arrangement illustrated in FIG. 2A, whereas the attractive forces act between the polarizable structures in the arrangement illustrated in FIG. 2B.

The electric field may be applied by using any of an alternate-current (AC) power supply or a direct-current (DC) power supply. The power supply to be used can be appropriately selected depending on a purpose of the device and a desired motion of the polarizable connection structure. The use of the AC power supply provides the advantage of preventing the occurrence of a chemical reaction of the electrolyte, which is a unique problem of the DC electric field, and the effects of suppressing a phenomenon in which the electric double layer is formed in the vicinity of an electrode applied with the electric field to cause a voltage drop. Moreover, by intermittently turning ON and OFF a DC voltage or an AC voltage by using a switch 5, a phenomenon can be suppressed, in which the system is placed in a new steady state by the continuous application of the voltage to slow down the motion of the polarizable structure, to thereby cause a more complex motion. In the abovementioned manner, the number of kinds of motions of the polarizable connection structure can be increased.

The polarizable connection structure of the present invention may further include a functional base for fulfilling a desired function. In the present invention, the functional base can be moved together with the polarizable connection structure in the liquid. Therefore, an apparent diffusion coefficient thereof increases. As a result, the function can be effectively fulfilled over a wide range. The functional base is a base having at least one of a size, shape, and a material, which is different from that of the polarizable structure to which the functional base is connected. The functional base means a substance which realizes some sort of action with a target due to mechanical, chemical, and electrical properties of the functional base.

For example, when a functional base which has a hydrophobic surface pattern is moved freely together with the polarizable connection structures in the electrolyte solution containing hydrophobic microparticles, micellar structures are formed around the hydrophobic microparticles, thereby efficiently stabilizing the hydrophobic microparticles. Moreover, when a functional base which has a function of recognizing and binding specifically a target substance is moved freely together with the polarizable connection structures in the electrolyte solution, the target substance can be more efficiently captured. However, the functions of the functional base are not limited to those described above, and can be arbitrarily set in accordance with the purpose of the device. As the function of recognizing and binding specifically the target substance, the functional base may have a surface shape which is complementary to a shape of the target substance, the function may be based on a complementary covalent bond or non-covalent bond pattern (antigen-antibody reaction or the like), or the function may be based on a bond with a functional group which reacts with an encapsulated drug or a functional group of the target substance. Therefore, the above-mentioned function is not particularly limited.

FIGS. 3A, 3B, 3C, and 3D are diagrams illustrating the polarizable connection structure of exemplary embodiments.

In the examples of FIGS. 3A and 3B, connector bodies 13c are curved linear elastic structures. Each of the polarizable structures includes an insulating surface 13a and a conductive surface 13b. For example, half of the surface may be coated with a metal thin film by vapor deposition or the like to form the conductive surface 13b. The coating with the metal film may be formed to have a patterned shape in view of the facility of manufacture or may be performed to have random orientations so as to move the polarizable connection structures more randomly.

At this time, a motion in the direction opposite to the conductive surface 13b occurs for the polarizable structure. Therefore, when the electric field is applied in a state in which the polarizable connection structure can migrate freely in the electrolyte solution, motions in different directions occur for the polarizable structures along the orientations of the conductive surfaces 13b. Therefore, the polarizable connection structures can move specifically in the electrolyte solution. In particular, when the polarizable structures are arranged such that conductive patterns are oriented in different directions as illustrated in FIG. 3A, a more random collective motion can be excited. On the other hand, when the polarizable structures are arranged such that the conductive patterns are always oriented in the same direction as illustrated in FIG. 3B, a unidirectional motion can be excited as the whole polarization connection structure.

In the example of FIG. 3C, polarizable structures 14a and 14b, each having an elliptic cylindrical shape, are connected to each other by curved linear deformable connector bodies 14c such that orientations of long axes of the polarizable structures 14a and 14b differ from each other. When a polarizable elliptic cylinder or elliptical sphere is used, a torque for generating a force for allowing a long-axis direction of the elliptic cylinder or elliptical sphere to be parallel to the applied electric field is generated by an induced-charge electroosmotic flow generated around thereof. Therefore, the polarizable elliptic cylinders are connected to each other by the connector bodies 14c such that the orientations of the long-axis directions may be different from each other, with the result that the polarizable connection structures can be moved in a complex manner.

In the example of FIG. 3D, polarizable structures 15a, each having an elliptic cylindrical shape, are connected to connector bodies 15c, each having axial rotation portions 15d. The polarizable connection structure has a tendency of greatly stretching in the direction of the electric field as a whole and of greatly contracting in a direction perpendicular to the electric field. Specifically, when a long-axis radius of the elliptic cylinder of the conductor is b, a short-axis radius thereof is c, a relationship: a=b/c holds, an angle formed between an electric-field vector E and the long axis is φ, the elliptic cylinder goes to rotate at an angular velocity Ω which satisfies: Ω=(εE²/μ)((α²−1)/(α²+1))sin2φ as a result of the generation of the induced-charge electroosmotic flow. In the expression, ε is a dielectric constant of the electrolyte solution, and μ is a viscosity coefficient of the electrolyte solution. For example, when μ=1 mPa·s, ε=80ε₀ (ε₀ is a dielectric constant of a vacuum), |E|=20 kV/m, φ=45 degrees, and α=4, the elliptic cylinder goes to rotate at Ω=250 rad/s. Moreover, when |E|=10 kV/m, the elliptic cylinder goes to rotate at Ω=62.5 rad/s.

The device of the present invention includes the electrolyte solution, the polarizable connection structure, a liquid chamber for containing the electrolyte solution and the polarizable connection structure therein, and an electric-field application unit for applying the electric field to the electrolyte solution.

By applying the electric field to the plurality of polarizable connection structures and the electrolyte solution with the electric-field application unit, the electroosmotic flow derived from the electric double layer is generated on the surfaces of the plurality of polarizable connection structures such that a hydrodynamic interaction is caused between the polarizable structures which are connected to each other by the connector bodies. As a result, a complex collective motion is generated in the group of the polarizable structures. In this manner, in accordance with a desired design purpose, micro-motions of the polarizable microstructures can be converted into a collective motion to fulfil the functions on a larger scale. The complex motion can be arbitrarily selected from a completely random motion, a unidirectional motion, and a motion having intermediate randomness in accordance with the purpose of the device. The degree of randomness can be appropriately set such that the device is designed to cause a desired motion.

For example, when a mean radius r (when a particle volume is v, the mean radius r can be obtained by a back calculation of: 4Πr³/3=v) of the polarizable structure is equal to or less than 5 μm, the Brownian motion of the polarizable structure is caused. Therefore, a more random motion of the polarizable structure can be caused. When the polarizable connection structure includes the above-mentioned functional base, a size of the functional base can also be set to 5 μm or less.

More specifically, when, for example, the electrolyte is water, a distance W between electrodes is 100 μm, a radius r of a spherical microparticle which is the polarizable structure is 3 μm, a gap between the microparticles in an electric-field OFF state is 3 μm, an AC voltage V₀ is 2 V, and a frequency is 100 Hz, an AC electric field at E₀=V₀/W=20 kV/m is generated by the application of the AC voltage. Around the particles, a flow at about U₀=ε_{w}rE₀²/μ0.85 mm/s is generated. As a result, the polarizable structures cause the hydrodynamic interaction therebetween. In this case, μ=1 mPa·s is a viscosity coefficient of water, ε_{w} is a water's dielectric constant, that is, 80ε₀, and ε₀ is a vacuum's dielectric constant. Moreover, when a mean concentration of the microparticles is set approximately equal to a mean concentration of the electrolyte by controlling the development of electroless plating for the microparticles, the collective motion can be relatively easily designed.

The present invention enables the functions provided by the collective motion to be fulfilled even in a small-sized device. Therefore, the size of the liquid chamber of the present invention is not particularly limited. The liquid chamber may have a size in the order of μm. Specifically, the distance between the electrodes may be less than 1 mm, more specifically, 1 μm or more and 1,000 μm or less, further specifically, from 500 μm to 10 μm.

The kind of electrolyte solution is not particularly limited. Pure water, a KOH aqueous solution, an NaOH aqueous solution, and the like can be used. There is a phenomenon that a flow rate of the electroosmotic flow generated by an increase in ion concentration is reduced. Therefore, the ion concentration of the KOH aqueous solution or the NaOH aqueous solution is desired to be set to 10 mM or less, more desirably, 1 mM or less.

A magnitude of the voltage to be applied can be appropriately selected depending on the material of the polarizable surface, the size and weight of the polarizable structure, and the like. The magnitude of the voltage can be set in the range of, for example, from 0.1 V to 100 V, from 0.5 V to 50 V, from 1 V to 10 V, from 1 V to 5 V, or from 1 V to 3 V.

In this case, a slipping velocity U₀ of the electroosmotic flow can be set in the range of from 0.1 mm/s to 2 mm/s although the slipping velocity U₀ depends on the size and weight of the polarizable structure.

The electroosmotic flow can cause a large flow at a small voltage. Therefore, according to the present invention, a specific or random collective motion with a large energy can be caused at a small voltage.

Therefore, the device of the present invention can be widely applied to mixing devices, microparticle stabilization devices, microparticle removal/separation devices, artificial muscles, and the like.

Hereinafter, Examples of the present invention are described in detail based on the consideration of specific numerical values.

### Example 1

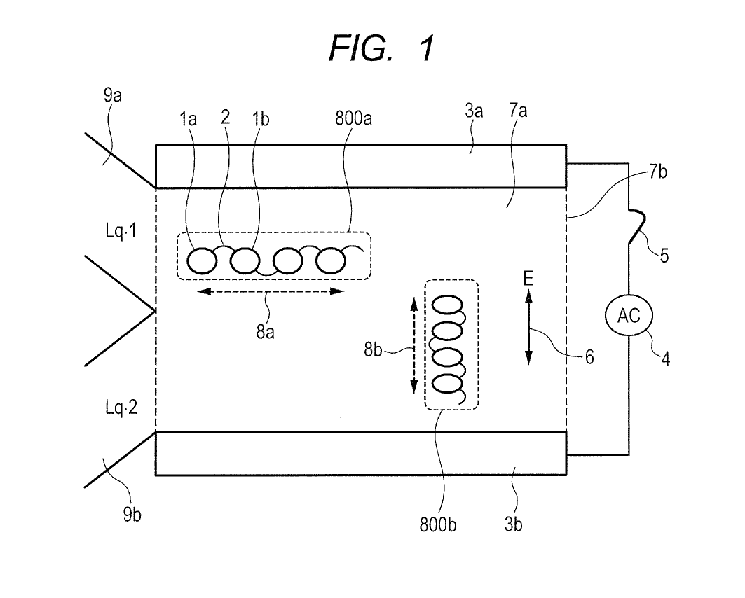

FIG. 1 is a diagram illustrating a device according to Example 1 of the present invention. The device of the present example includes a liquid chamber 7b filled with an electrolyte 7a, a pair of parallel electrodes 3a and 3b as electric-field application units, and an alternate-current (AC) power supply 4. In the electrolyte 7a, polarizable connection structures 800a and 800b move freely. Each of the polarizable connection structures 800a and 800b includes a plurality of polarizable structures 1a and 1b, each having a polarizable conductive part, and mobile or deformable connector bodies 2 which connect the polarizable structures 1a and 1b to each other. The device of the present example may include a power-supply application switch 5, and flow paths 9a and 9b for supplying or discharging a liquid to/from the liquid chamber 7b. When two kinds of liquid are to be mixed by the device of the present example, different kinds of liquid can be supplied from the two flow paths 9a and 9b, respectively. The polarizable connection structures freely move in the electrolyte 7a by the Brownian motion of each of the polarizable structures itself and a motion due to an induced-charge electroosmotic flow generated by the application of the electric field. As a result, the polarizable connection structures have various orientations including specific orientations such as a state 8a in which a direction of connection of the polarizable structures is approximately perpendicular to a direction 6 of the electric field and a state 8b in which the direction of connection of the polarizable structures is approximately parallel to the direction 6 of the electric field.

In the present example, as each of the polarizable structures 1a and 1b, a spherical or elliptical spherical buoyant resin base made of styrene or the like, which is subjected to electroless plating of gold to provide conductivity only to a surface, is used. As the connector body 2, a curved linear insulating fiber resin having elasticity, such as nylon or Teflon (trade name) is used.

For each of the polarizable connection structures 800a and 800b, the following is supposed. The polarizable structures 1a and 1b, each having a spherical shape with a radius of 3 μm or an elliptical spherical shape having a long axis of 4 μm and a short axis of 2 μm, are connected by the connector bodies 2 having a length of 9 μm through thermofusion or pinning. For one polarizable connection structure, it is supposed that three or four polarizable structures are connected. As the electrolyte solution, water is used. One to twenty polarizable connection structures are moved freely in the liquid chamber 7b having dimensions: (100 μm)×(200 μm)×(500 μm). The AC voltage at 2 V (100 Hz) is applied such that the electroosmotic flow at 0.85 mm/s is generated around the polarizable structures 1a and 1b. The polarizable connection structures 800a and 800b move randomly in the liquid chamber 7b. Therefore, an apparent diffusion coefficient can be set large. Therefore, it is confirmed that the liquid in the liquid chamber can be efficiently mixed.

For example, when a plurality of liquids including the electrolyte are introduced into the liquid chamber 7b through the flow paths 9a and 9b as illustrated in FIG. 1, the liquids without the electric field application mix with each other only by molecular diffusion in a micro flow path having a small Reynolds number. However, when the electric field is generated by the electrodes 3a and 3b to induce a random motion of the polarizable connection structures in which the plurality of polarizable structures 1a and 1b are connected to each other by the deformable connector bodies 2, the mixture in the liquid chamber 7b can be accelerated. In the present example, the Brownian motion of the polarizable structures is caused. Therefore, the mixing effect can be further increased. Moreover, when the AC electric field is intermittently applied by the switch 5, a steady state can be avoided. Therefore, the random motion can be maintained. As a result, mixing performance can be increased.

In this case, when the polarizable connection structure having the connection structure illustrated in FIG. 3A or 3C is used in the device illustrated in FIG. 1, an extremely varied and random collective motion of the polarizable connection structure occurs with respect to the direction 6 of the electric field. Therefore, the mixing performance can be improved. Moreover, as illustrated in FIG. 3A, when the polarizable structures are arranged such that orientations of the conductive patterns become different for each of the polarizable structures, a more random collective motion can be induced. As a result, the mixing performance can be improved.

Moreover, when the polarizable connection structure having a connection structure illustrated in FIG. 3D is used for the device illustrated in FIG. 1, a large stretching/contracting motion can be caused in the direction 6 of the electric field for each of the polarizable connection structures. As a result, the mixing performance can be improved.

Moreover, the diffusion coefficient of the particles having an equivalent particle radius r by the Brownian motion can be expressed as: D=kT/(6Πrμ) according to the Einstein-Stokes relational expression. Therefore, as the particle radius r is set smaller, the effect of the Brownian motion can be increased. In the relational expression, k is a Boltzmann constant, T is an absolute temperature, and μ is a viscosity coefficient of a fluid around the particle. The equivalent particle radius r can be derived from V=(4Πr³)/3 for the particles having the volume V. Specifically, in the case of the polarizable structure particles in water, when the viscosity is: μ=1 mPa·s and the radius is: r=3, 0.3, and 0.03 μm, the diffusion constant is: D=7.33×10⁻¹⁴, 7.33×10⁻¹³, and 7.33×10⁻¹² m²/s, respectively. A diffusion distance (Dt)^{-0.5} for one second is 0.27, 0.85, and 2.7 μm, respectively.

Moreover, in this case, by the application of the electric field: E₀=20 kV/m, a flow at U₀=ε_{w}rE₀²/μ=about 0.85 mm/s, 0.085 mm/s, and 0.0085 mm/s is generated around the polarizable structure. As a result, a fluid interaction is caused between the polarizable structures. Specifically, in the mixing device according to Example 1, in the liquid chamber containing the plurality of fluids to be mixed, there are provided the connected structures in which the polarizable structure particles having the equivalent particle radius of 5 μm or less are connected in a chain-like fashion by the deformable connector bodies which can change the relative position between the polarizable structures. By the application of the electric field, a motion, which is a complex combination of the Brownian motion and the motion derived from the induced-charge electroosmosis, is induced to enable the effective mixture of fluids.

### Example 2

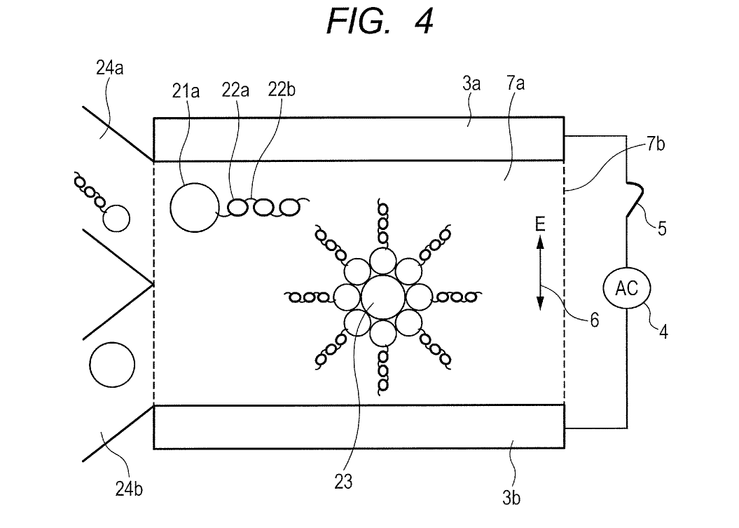

FIG. 4 illustrates a device according to Example 2 of the present invention. The device according to Example 2 has the same configuration as that of Example 1 with the exception that a functional base 21a is connected to polarizable structures 22a similar to those of Example 1 by connector bodies 22b. By adding the functional base 21a to the polarizable connection structure as described in Example 1, the functional base 21a also moves in the liquid chamber in a complex manner to be diffused widely. Therefore, the functions of the functional base 21a can be effectively fulfilled over a wide range in the liquid chamber 7b.

In the present example, the polarizable connection structure in which the spherical functional base 21a with a radius of 5 μm, which has a surface having a hydrophobic part, is used. As the polarizable structure 22a, a spherical polarizable structure having a radius of 3 μm is used. For one polarizable connection structure, three polarizable structures 22a are connected. As the functional base 21a having the surface with the hydrophobic part, a base having a hydrophobic area over the entire surface may be used. Alternatively, another substance may be provided to a part of the surface of the base to provide a hydrophobic property. The functional base 21a of the present example has the hydrophobic property, and therefore moves freely in the liquid chamber together with the polarizable connection structure. When the functional base 21a encounters a hydrophobic microparticle 23, the functional base 21a has a function of easily adhering to a surface of the microparticle 23. Further, in the present example, polarizable structures, each having a hydrophilic surface, are used as the polarizable structures 22a and 22b. Otherwise, the same conditions as those of Example 1 are used.

When the polarizable connection structures (nine in number in the present example) of the present example are moved freely in the liquid chamber 7b, the polarizable connection structures cause a complex motion to move inside the liquid chamber 7b. Therefore, a micellar structure is formed around the hydrophobic microparticle 23. As a result, the hydrophobic particle 23 can be efficiently stabilized over a wide range in the liquid chamber 7b. In FIG. 4, the polarizable connection structures serving as a stabilizing agent may be supplied to the liquid chamber 7b through a flow path 24a, whereas the microparticles desired to be stabilized may be supplied to the liquid chamber 7b through a flow path 24b.

### Example 3

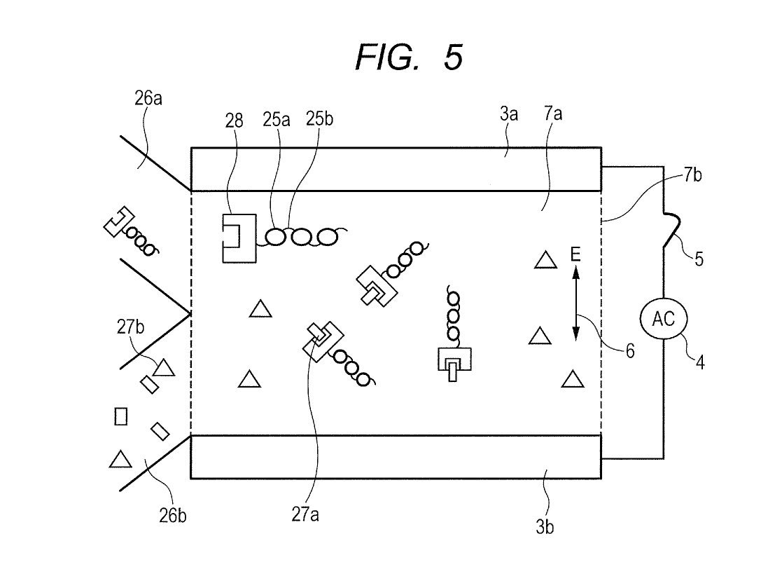

FIG. 5 illustrates a device according to Example 3 of the present invention. The device of Example 3has the same configuration as that of Example 2 with the exception that a functional base 28 is provided with a function of recognizing specifically a target substance 27a. The functional base 28 is a cuboid having dimensions: (height 10 μm)×(width 10 μm)×(depth 5 μm). By forming a recess having dimensions: (height 6 μm)×(width 5 μpm)×(depth 5 μm) on an upper surface of the functional base 28, the functional base 28 has a concave shape. When the four polarizable connection structures including the functional base 28 connected to the polarizable structure are moved freely in the liquid chamber 7b, the structures 27a, each having a shape fittable to an unevenness structure of the functional base 28, can be specifically captured over a wide range in the liquid chamber 7b. Therefore, the target substance 27a which binds specifically to the functional base 28 and a substance 27b which does not bind specifically to the functional base 28 can be efficiently separated and removed.

Alternatively, in FIG. 5, a plurality of flow paths 26a and 26b may be provided such that the polarizable connection structure serving as a separation or removal material is supplied to the liquid chamber 7b through the flow path 26a, whereas a microparticle aggregate containing the microstructures desired to be separated or removed is supplied to the liquid chamber 7b through the flow path 26b.

### Example 4

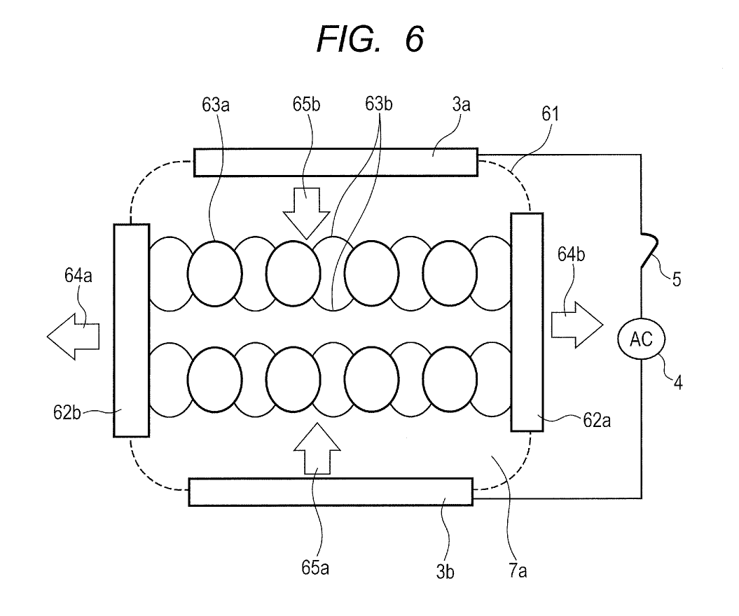

FIG. 6 illustrates a device according to Example 4 of the present invention. The device according to Example 4 has the same configuration as that of Example 1 with the exception that a deformable liquid chamber 61 is provided and wall surfaces 62a and 62b of the liquid chamber 61 on both sides and at least a part of the polarizable connection structure including polarizable structures 63a are connected to each other. The deformable liquid chamber 61 is configured to include, for example, the rigid wall surfaces 62a and 62b and deformable liquid chamber wall surfaces. The polarizable connection structures may be directly connected to the wall surface 62a or 62b by connector bodies 63b or may be connected indirectly thereto through intermediation of individually provided connection members. In this case, the wall surfaces 62a and 62b on both sides may be configured to be connected to each other by the polarizable connection structures by connecting one end of each of the polarizable connection structures to the wall surface 62a and another end thereof to the wall surface 62b.

In the present example, a plurality of units, each including spherical particles having surfaces coated with a thin metal film connected to each other by a pair of curved elastic insulating fibers in a linear fashion, are connected to both of the rigid wall surfaces 62a and 62b forming a part of the wall surfaces of the deformable liquid chamber. In this case, by applying the electric field in a direction perpendicular to an axis of the linear units by using the pair of parallel electrodes 3a and 3b, the electroosmotic flow can be generated between the spherical particles to cause a hydrodynamic repulsion (see FIG. 2A) between the particles. As a result of the configuration described above, when the AC voltage is applied, a tensile stress acts in directions 64a and 64b, whereas a compressive stress acting in directions 65a and 65b. As a result, the liquid chamber 61 can be deformed. Moreover, when the AC voltage is turned OFF by the switch 5, the polarizable connection structures return to the original state by an elastic force of the connector bodies 63b. Therefore, the liquid chamber can be returned to have the original shape.

In Example 4, the polarizable structures 63a, each having a radius of 3 μm, are used. The ten polarizable structures 63a are connected to each other by two deformable connectors 63b for each connection to obtain the polarizable connection structure having a length of 93 μm. The two polarizable connection structures are connected to the wall surface 62a or 62b of the liquid chamber 61 having dimensions: (height 100 μm)×(width 93 μm)×(depth 100 μm) by thermofusion. Otherwise, the voltage is applied under the same conditions as those of Example 1. Then, a high stretching/contracting function of the polarizable connection structure, which is derived from the generation of the induced-charge electroosmotic flow, can be specifically derived. Therefore, the device of the present example can be used, for example, as an actuator.

### Example 5

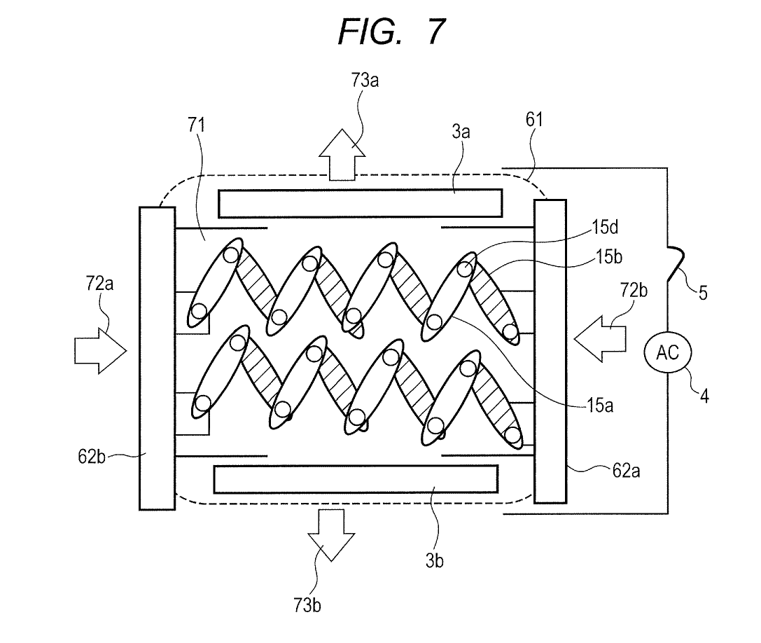

FIG. 7 illustrates a device according to Example 5 of the present invention. The device of Example 5 has the same configuration as that of Example 4 except for the following. Specifically, in Example 5, the polarizable connection structure is a unit formed by connecting a series of the elliptic cylindrical polarizable structure 15a, the insulating oval flat plate 15b, and the adjacent elliptic cylindrical polarizable structure 15a alternately in the stated order in a Z-like pattern by using the axial rotation portions 15d. The polarizable connection structures may be directly connected to the wall surface 62a or 62b. Alternatively, as illustrated in FIG. 7, the polarizable connection structures may be connected indirectly through intermediation of connection members provided to the rigid wall surfaces 62a and 62b. Guides 71 for a movable cylinder, which have transmitting walls through which a liquid can pass, may be provided to the rigid wall surfaces 62a and 62b, such that the pair of parallel electrodes 3a and 3b forming a part of the movable cylinder having the transmitting walls through which the liquid can pass, which forms pairs with the guides 71, may be used. By applying the electric field in a direction approximately perpendicular to an axis of each of the zigzag-pattern polarizable units illustrated in FIG. 7, the electroosmotic flow is generated around the elliptic cylindrical polarizable structure. As a result, a hydrodynamic torque to orient a long axis of the elliptic cylinder in the direction of application of the electric field is generated. As a result, the compressive stress in directions 72a and 72b and the tensile stress in directions 73a and 73b can be generated on the wall surfaces of the deformable liquid chamber 61 when the AC voltage is applied. As a result, the rigid walls 62a and 62b with guides can be greatly moved in the directions 72a and 72b. Moreover, when the AC voltage is turned OFF by the switch 5, the polarizable connection structures return to the original state by the elastic forces of the connector bodies 63a and 63b. The liquid chamber 61 can also return to the original position by the elastic force.

In Example 5, the elliptic cylindrical polarizable structures 15a, each having the long axis of 20 μm and the short axis of 5 μm, are used. Eleven polarizable structures 15a are connected by pinning so as to be axially rotatable about the connector bodies 15b, thereby forming the polarizable connection structure having a length of 170 μm. Two polarizable connection structures are connected to the wall surface 62a or 62b of the liquid chamber 61 having dimensions: (100 μm)×(170 μm)×(500 μm) by the axial rotation portions. Otherwise, the voltage is applied under the same conditions as those of Example 1. Then, a high stretching/contracting function of the polarizable connection structure, which is derived from the generation of the induced-charge electroosmotic flow, can be specifically derived. Therefore, the device of the present example can be used, for example, as an actuator.

### Example 6

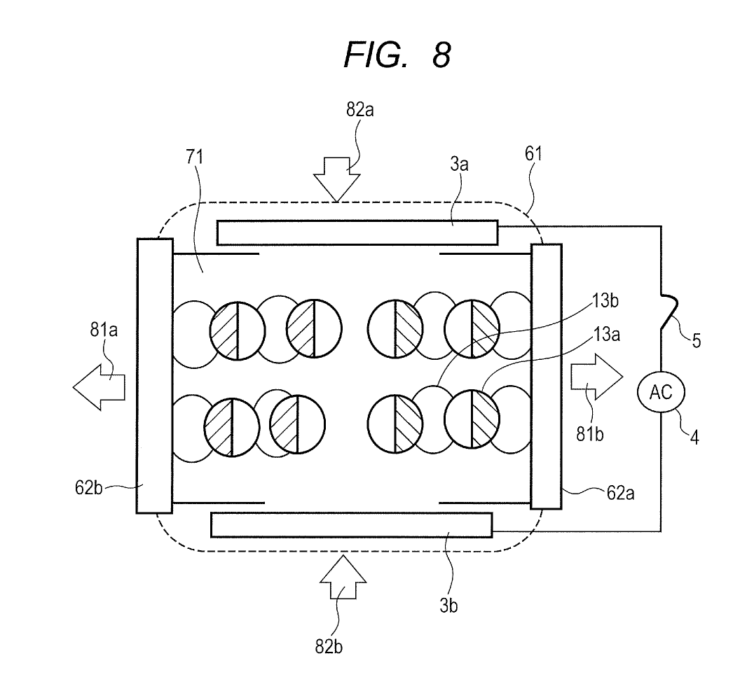

FIG. 8 illustrates a device according to Example 6 of the present invention. The device of Example 6 has the same basic configuration as that of Example 4 except for the following. Specifically, in the device of Example 6, only half of the surface of the spherical polarizable structure 13a is coated with the thin metal film. The spherical polarizable structures 13a are arranged such that an orientation of a boundary between the metal-coated portion (metal surface) and an uncoated surface (insulating surface) becomes approximately parallel to the direction of application of the electric field. The polarizable structures 13a may be used to form a unit in which the polarizable structures 13a are connected linearly by using the deformable insulating connector bodies 13b, each having a curved elastic structure. The polarizable connection structures may be directly connected to the wall surface or may be connected indirectly through intermediation of connection members provided to the wall surface, as in the case of Example 5. In Example 6, each of the polarizable structures 13a or the unit including the polarizable structures 13a is connected to only any one of the rigid wall surfaces 62a and 62b. Example 6 is the same as Example 4 with the exception that the polarizable structures 13a are connected to only any one of the rigid wall surfaces 62a and 62b connected to the guides 71 for the movable cylinder, which form a part of the wall surface of the deformable liquid chamber 61 having elasticity and that the pair of parallel electrodes 3a and 3b forming a part of the movable cylinder having the transmitting walls through which the liquid can pass, which forms the pair with the guides 71, is used.

When the electric field is applied in the direction approximately perpendicular to the orientation of the boundaries between the metal-coated surfaces and the uncoated surfaces of the polarizable structures 13a illustrated in FIG. 8, the electroosmotic flow is generated only around the metal-coated portion of each of the polarizable structures 13a. As a result, a hydrodynamic translational force in the direction perpendicular to the direction of application of the electric field is generated in each of the polarizable structures 13a. When the metal-coated portion of the polarizable structure 13a is oriented toward the wall surface 62a or 62b, a motion toward the wall surface is caused in the polarizable structure 13a when the AC voltage is applied. As a result, a tensile stress in directions 81a and 81b illustrated in FIG. 8 and a compressive stress in directions 82a and 82b are generated. When the metal-coated portion of each of the polarizable structures 13a is oriented in a direction opposite to the wall surface 62a or 62b, a motion away from the wall surface is caused in the polarizable structure 13a when the AC voltage is applied. As a result, the compressive stress in the directions 81a and 81b and the tensile stress in the directions 82a and 82b illustrated in FIG. 8 are generated. In this manner, the rigid wall surfaces 62a and 62b with the guides 71 can be moved greatly in the directions 81a and 81b. Moreover, when the AC voltage is turned OFF by the switch 5, the polarizable connection structures return to the original state by the elastic force of the connector bodies 13b. As a result, the liquid chamber 61 also returns to the original position by the elastic force.

In Example 6, the polarizable structures 13a, each having a radius of 10 μm, are used. Four polarizable structures 13a are connected by two deformable connector bodies 13b for each connection, thereby forming the polarizable connection structure having a length of 60 μm. Four polarizable connection structures 13a are connected by thermofusion such that two polarizable connection structures 13a are connected to the wall surface 62a of the liquid chamber 61 having dimensions: (height 100 μm)×(width 200 μm)×(depth 500 μm) and the other two polarizable connection structures 13a are connected to the wall surface 62b. The orientations of the polarizable structures 13a are aligned such that the metal-coated portions are located on the side opposite to the wall surfaces connected thereto. Otherwise, the voltage is applied under the same conditions as those of Example 1. Then, a high stretching/contracting function of the polarizable connection structure, which is derived from the generation of the induced-charge electroosmotic flow, can be specifically derived. Therefore, the device of the present example can be used, for example, as an actuator.

When the electric field is applied to the electrolyte solution containing the structures of the present invention, the electroosmotic flow derived from the electric double layer is generated around the surfaces of the plurality of polarizable structures. As a result, the specific hydrodynamic interaction is caused between the polarizable structures. Therefore, a specific motion as a group is caused in the group of the polarizable structures which are connected to each other by the connector bodies. The micro-motions of the polarizable microstructures can be converted into a collective motion. As a result, the functions can be fulfilled on a larger scale.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2013-157365, filed Jul. 30 2013, which is hereby incorporated by reference herein in its entirety.

What is claimed is:

1. A polarizable connection structure, comprising:
a plurality of polarizable structures, each having an electrically polarizable conductive part on a surface thereof; and
a connector body having one of mobility and deformability, for connecting the plurality of polarizable structures to each other.

2. The polarizable connection structure according to claim 1, wherein:
each of the plurality of polarizable structures has the polarizable part on the surface thereof, the polarizable part being patterned; and
the plurality of polarizable structures are connected such that orientations of the patterned polarizable parts become different between adjacent ones of the plurality of polarizable structures.

3. The polarizable connection structure according to claim 1, wherein:
each of the plurality of polarizable structures has the polarizable part on the surface thereof, the polarizable part being patterned; and
the plurality of polarizable structures are connected such that orientations of the patterned polarizable parts become the same between adjacent ones of the plurality of polarizable structures.

4. The polarizable connection structure according to claim 1, wherein each of the plurality of polarizable structures has one of an elliptical spherical shape and an elliptic cylindrical shape.

5. The polarizable connection structure according to claim 4, wherein the connector body is bonded to each of the plurality of polarizable structures by an axial rotation portion to connect the plurality of polarizable structures such that a series of the polarizable structure, the connector body, and the adjacent polarizable structure is arranged in a Z-like pattern.

6. The polarizable connection structure according to claim 1, further comprising a functional base having at least a size, a shape, or a material, which is different from a size, a shape, or a material of the plurality of polarizable structures, the functional base being connected by the connector body having one of the mobility and the deformability.

7. The polarizable connection structure according to claim 6, wherein the functional base has a function of binding specifically to a target substance.

8. The polarizable connection structure according to claim 1, wherein each of the plurality of polarizable structures has a spherical shape with a radius between 0.01 μm or more and 1,000 μm or less.

9. The polarizable connection structure according to claim 1, wherein the polarizable conductive part comprises a metal thin film.

10. The polarizable connection structure according to claim 1, wherein the connector body has an insulating property.

11. The polarizable connection structure according to claim 1, wherein the connector body comprises a fiber resin.

12. A device, comprising:
the polarizable connection structure according to claim 1;
a liquid chamber for containing the polarizable connection structure and an electrolyte solution; and
an electric-field application unit.

13. The device according to claim 12, wherein:
the liquid chamber is deformable; and
at least a part of the polarizable connection structure is connected to the liquid chamber.

14. The device according to claim 12, wherein:
the electric-field application unit comprises a set of electrodes arranged in parallel; and
a distance between the electrodes is between 1 μm or more and 1,000 μm or less.

15. The device according to claim 12, wherein:
the liquid chamber includes one of a flow path for supplying a fluid and a flow path for discharging a fluid;
each of the plurality of polarizable structures has a spherical shape with a diameter equal to 5 μm or less; and
the liquid is mixed through application of an electric field with the electric-field application unit.

16. The device according to claim 12, wherein:
the polarizable connection structure includes a functional base having a hydrophobic surface pattern;
the liquid chamber includes a flow path for supplying the liquid containing at least the polarizable connection structure and a hydrophobic microparticle; and
the hydrophobic microparticle is stabilized through application of an electric field with the electric-field application unit.

17. The device according to claim 12, wherein:
the polarizable connection structure includes a functional base including an unevenness structure formed on a surface thereof;
the liquid chamber includes a flow path for supplying a liquid containing at least the polarizable connection structure and a microparticle fittable to the unevenness structure; and
the microparticle fittable to the unevenness structure is separated or removed through application of an electric field with the electric-field application unit.

18. The device according to claim 13, wherein:
each of the plurality of polarizable structures has an elliptic cylindrical shape with a surface coated with a thin metal film to have a patterned shape; and
the liquid chamber is deformed through application of an electric field with the electric-field application unit.

19. The device according to claim 13, wherein:
the plurality of polarizable structures are connected linearly;
the polarizable connection structure connected to a rigid wall portion of the deformable liquid chamber; and
a hydrodynamic repulsion against the rigid wall portion is generated in the polarizable connection structure through application of an electric field with the electric-field application unit.

20. The device according to claim 13, wherein:
each of the plurality of polarizable structures has an elliptic cylindrical shape;
the connector is bonded to the plurality of polarizable structures by an axial rotation portion to connect the plurality of polarizable structures such that a series of the polarizable structure, the connector body, and the adjacent polarizable structure is arranged in a Z-like pattern;
the polarizable connection structure is connected to a rigid wall portion of the deformable liquid chamber; and
a torque derived from an electroosmotic flow is generated around the plurality of polarizable structures through application of an electric field with the electric-field application unit.

21. The device according to claim 13, wherein:
each of the plurality of polarizable structures includes a metal surface and an insulating surface;
the connector connects the plurality of polarizable structures in a linear fashion such that orientations of the metal surfaces become the same;
only one side of the polarizable connection structure is connected to a rigid wall portion forming a part of a wall surface of the deformable liquid chamber; and
a translational force is generated in the polarizable connection structure through application of an electric field with the electric-field application unit.
